(19) United States
(12) Patent Application Publication
(10) Pub. No.: US 2013/0002304 A1
(43) Pub. Date: Jan. 3, 2013

(54) THRESHOLD TRACKING EDGE DETECTION

(76) Inventors: Pio Balmelli, Austin, TX (US); Eduardo Viegas, Austin, TX (US)

(21) Appl. No.: 13/173,472

(22) Filed: Jun. 30, 2011

(51) Int. Cl. G01R 29/02; H03L 7/06

(52) U.S. Cl. 327/33; 327/155

(57) ABSTRACT

Techniques are disclosed relating to tracking edges of a signal of a buffer circuit. In one embodiment, an apparatus is disclosed that includes a sampling circuit configured to sample a pulse width modulation (PWM) signal to generate a threshold voltage based on an average of the high and low voltage levels of the PWM signal and to provide the threshold voltage to an input of a comparator of the apparatus. The comparator is configured receive the threshold voltage and the PWM voltage and perform edge detection on the threshold voltage and PWM signal.

### BACKGROUND

1. Technical Field

This disclosure relates generally to circuits, and, more specifically, to amplifiers.

2. Description of the Related Art

Pulse width modulation (PWM) systems are used to generate analog signals from digital data. PWM signals can be used to drive an H-bridge or similar device (such as an amplifier or other buffer circuit) to achieve high power and high efficiency amplification. An ideal H-bridge is simply a digital buffer that reproduces the digital waveforms with higher output amplitude. Preferably, the buffer has a fixed delay, providing edge transitions (rising or falling) at its output at a fixed time offset from the input.

Unfortunately, the propagation delay of a practical H-bridge implementation may be variable and/or signal dependent. In class D amplifiers, such as those used in audio applications, propagation delay variations through an H-bridge or buffer circuit represents a non-linearity. Such a non-linearity can result in degraded Total Harmonic Distortion (THD) of the audio signal. If spectral energy spreading techniques have been applied to the PWM signal, such a non-linearity can cause high frequency noise to fold into the lower frequencies of the audio band or the band of interest, resulting in harmonic distortion or degraded signal-to-noise (SNR) ratio.

### SUMMARY

The present disclosure describes systems and methods for tracking edges of a signal of a buffer circuit.

In one embodiment, an apparatus is disclosed. The apparatus includes a sampling circuit configured to sample a PWM signal to generate a threshold voltage based on an average of the high and low voltage levels of the PWM signal and to provide the threshold voltage to an input of a comparator of the apparatus. The comparator is configured to receive the threshold voltage and the PWM signal and perform edge detection on the PWM signal using the threshold voltage.

In another embodiment, an apparatus is disclosed that includes an H-bridge circuit coupled to a sampling circuit, a comparator, and a latency locked loop (LLL) circuit. The H-bridge is configured to provide a PWM signal to the sampling circuit and the comparator. The sampling circuit is configured to generate a threshold voltage based on samples of the PWM signal and is further configured to provide the threshold voltage to the comparator. The comparator is configured to compare the threshold voltage with the PWM voltage and provide the resulting comparison to the LLL circuit. The LLL circuit is configured to generate a compensated PWM signal based on the comparison result and is further configured to provide the compensated PWM voltage to the H-bridge circuit.

In yet another embodiment, a method is disclosed. The method includes a sampling circuit sampling a PWM signal. The method further includes the sampling circuit generating a threshold voltage based on the average of the high and low voltage levels of the sampled PWM signal. The method further includes a comparator receiving the PWM signal and threshold voltage. The method further includes the comparator performing edge detection on the received PWM signal.

### BRIEF DESCRIPTION OF THE DRAWINGS

FIG. 1 is a block diagram illustrating one embodiment of a circuit that includes a threshold tracking edge detector.

FIG. 2 is a block diagram illustrating one embodiment of a latency locked loop (LLL) circuit that includes a slicer circuit.

FIG. 3 is a block diagram illustrating one embodiment of a slicer circuit.

FIG. 4A is a circuit diagram illustrating one embodiment of a sampling circuit of the slicer circuit.

FIG. 4B is a timing diagram illustrating switch closing behavior of the sampling circuit of FIG. 4A.

FIG. 5A is a circuit diagram illustrating another embodiment of a sampling circuit of the slicer circuit.

FIG. 5B is a timing diagram illustrating switch closing behavior of the sampling circuit of FIG. 5A.

FIG. 6 is a flowchart illustrating operation of one embodiment of a slicer circuit.

### DETAILED DESCRIPTION

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Configured To.” Various units, circuits, or other components may be described or claimed as “configured to” perform a task or tasks. In such contexts, “configured to” is used to connote structure by indicating that the units/circuits/components include structure (e.g., circuitry) that performs those task or tasks during operation. As such, the unit/circuit/component can be said to be configured to perform the task even when the specified unit/circuit/component is not currently operational (e.g., is not on). Reciting that a unit/circuit/component is “configured to” perform one or more tasks is expressly intended not to invoke 35 U.S.C. §112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue.

“First,” “Second,” etc. As used herein, these terms are used as labels for nouns that they precede, and do not imply any type of ordering (e.g., spatial, temporal, logical, etc.). For example, in a sampling circuit having three capacitors, the terms “first” and “second” capacitors can be used to refer to any two of the three capacitors.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

The present disclosure describes a slicer circuit that is configured to generate a threshold voltage as part of edge detection circuitry. As will be described below, in various embodiments, a slicer circuit may include a comparator and a sampling circuit configured to sample a voltage and generate an average/threshold voltage based on the voltage samples.

In one embodiment, the sampling circuit described herein is configured to alternately sample a positive phase voltage and negative phase voltage of a PWM signal. As described herein, sampling a positive and negative phase voltage is used to describe sampling a high voltage level and a low voltage level, respectively, of a PWM signal or other signal in which the duty cycle is varied. For ease of explanation, the various embodiments are described in terms of a PWM signal. It is appreciated, however, that other signals in which the duty cycle is intentionally or unintentionally varied may benefit from similar techniques and structures. Over time, alternately sampled positive and negative phase voltages may be averaged and approximate an average of the high and low voltage levels of the PWM signal. Accordingly, in such an embodiment, the approximated average voltage may be provided to one input of a comparator to compare with the PWM signal itself. The resulting comparison, in the form of a digital edge timing waveform, in some embodiments, may be used for feedback in a compensation circuit. Generating an average voltage based on actual samples of the PWM signal may allow the compensation circuit to better account for errors introduced at the sampling circuit itself. As a result, SNR and THD may be improved.

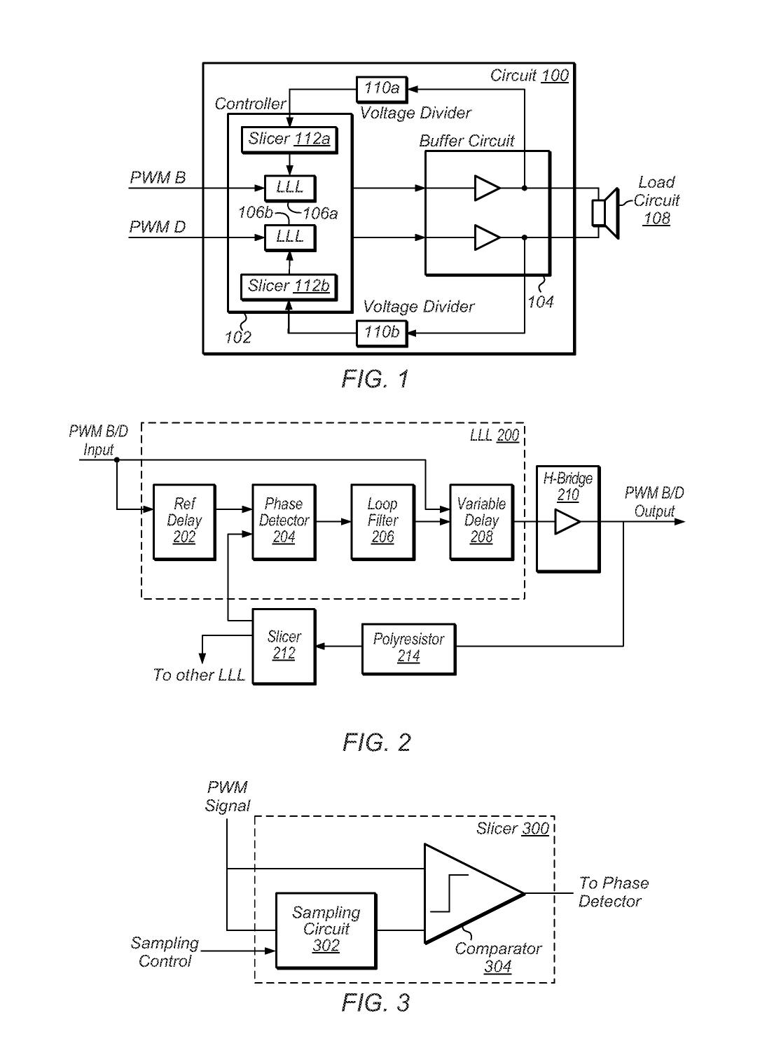

Turning now to FIG. 1, a block diagram of a circuit 100 is depicted. In the illustrated embodiment, circuit 100 is configured as a class D amplifier (also referred to as a “digital amplifier” or a “switching amplifier”). In another embodiment, circuit 100 may be configured as a buck DC-DC converter. In yet another embodiment, circuit 100 may be configured as a light-emitting-diode (LED) driver.

In the illustrated embodiment, circuit 100 includes controller 102, voltage dividers 110a and 110b, and buffer circuit 104. The illustrated controller 102 includes two latency locked loop (LLL) circuits 106, which may also be referred to edge timing error compensation circuits, as well as slicers 112a and 112b. Circuit 100 may also include load circuit 108. As shown, controller 102 is coupled to buffer circuit 104, which is coupled via feedback to slicers 112a and 112b and LLL circuits 106 of controller 102. The feedback from buffer circuit 104 to controller 102 may be via a voltage divider 110a or 110b that can be implemented in some embodiments as a passive polyresistor divider. In some embodiments, voltage dividers 110a and 110b may reside in controller 102, while in other embodiments, they may reside as separate components of circuit 100. In some embodiments, buffer circuit 104 and controller 102 may reside on different dies. In some embodiments, circuit 100 is coupled to load circuit 108 via an output node.

Each LLL circuit 106 may be configured to receive a digital input signal. For example, each LLL circuit may receive a pulse width modulation (PWM) signal (e.g., PWM B and PWM D, respectively). LLL circuits 106a and 106b include feedback inputs to receive the PWM output signals (e.g., PWM B output and PWM D output, respectively) from buffer circuit 104 through a respective slicer 112. In some embodiments, controller 102 includes one or more polyresistors 110 configured to receive a high voltage signal (e.g. +/−24V) and divide it down to a lower voltage signal (e.g., +/−3V). In some embodiments, voltage dividers 110a and 110b may reside in a component other than controller 102, for example, as a separate component in circuit 100. Thus, in some embodiments, the PWM output signal that each LLL circuit 106 receives may be a divided down version of the actual PWM output signal. Each LLL circuit 106 may be configured to provide an adjusted PWM signal to buffer circuit 104. The adjusted PWM signal may include a controlled delay to produce a substantially constant delay from the signal input to LLL circuit 106 to the signal at the output of buffer circuit 104.

Buffer circuit 104 may be configured to receive an adjusted PWM signal from each LLL circuit 106 of controller 102. Buffer circuit 104 may be a conventional H-bridge driver circuit (as shown in FIG. 2), an amplifier, or other circuit that can be used to drive a load. As depicted in FIG. 1, buffer circuit 104 includes two halves (e.g., two half H-bridges). Each half may amplify (and delay) pulses within the received adjusted PWM signal and may output a corresponding output PWM signal. The output PWM signal may include some propagation delay (e.g., edge transition propagation delay). Propagation delays may vary based on a variety of factors including: size of transistors used (not shown in FIG. 1) within buffer circuit 104, the load current provided to load circuit 108, and any inductive and/or capacitive connection present (not shown in FIG. 1) in buffer circuit 104, etc. Buffer circuits may use transistor devices that have large gate-to-source capacitances which may introduce delays in switching in response to transitions within an input signal. Any propagation delay may also vary according to the particular transition edge. For example, a rising edge transition may have a different propagation delay than that of a falling edge transition. For differential signals where the content of interest is contained in the difference between the signals, such propagation delays can lead to distortion of content. Propagation delay may also vary according to a signal dependent load current that causes distortion of content.

Load circuit 108 may be any suitable device. In the illustrated embodiment, load circuit 108 is depicted as a speaker. In another embodiment, load circuit 108 may be a light source such as an LED. In some embodiments, load circuit 108 may be an antenna for transmitting signals. In other embodiments, load circuit 108 may be an inductive/capacitive network.

In some embodiments, LLL circuit 106 may use feedback from the output PWM signal to determine propagation delay variations with respect to edge transition timing within the output signal and to adjust timing of subsequent edge transitions to produce a substantially constant propagation delay from the input of LLL circuit 106 to the output of buffer circuit 104. Some components and mismatches between component elements of LLL circuit 106 can introduce measurement errors, which can cause circuit 100 to produce output signals having a substantially fixed propagation delay with measurement-induced errors in those output signals. Such measurement-induced errors can include transition edge pulses, which can introduce noise or distortion at load circuit 108 within a particular frequency band of interest.

Turning now to FIG. 2, a block diagram of one embodiment of LLL circuit 200 is depicted. In the illustrated embodiment, LLL circuit 200 is coupled to a slicer circuit that may be coupled to another LLL circuit (not shown) and to a buffer circuit, shown as H-bridge 210. Note that H-bridge 210 may actually be a half H-bridge. Slicer circuit 212 is coupled to phase detector 204 of LLL circuit 200. Phase detector 204 is coupled to loop filter 206, which is coupled to variable delay circuit 208, which is coupled to H-bridge 210. Reference delay is configured to receive PWM B/D input. Reference delay is coupled to phase detector 204. Variable delay circuit 208 is also configured to receive PWM B/D input. In various embodiments, one or more of reference delay circuit 202, phase detector 204, loop filter 206, and variable delay circuit 208 can be implemented as digital components.

In the illustrated embodiment, LLL circuit 200 can be used to dynamically adjust the propagation delay to provide a substantially constant total propagation delay from the inputs to the outputs of the circuit by controlling timing of rising and falling edge transitions independent of input waveform and independent of the load current. LLL circuit 200 may use timing feedback from the output of the H-bridge to dynamically adjust timing edge placement at the input of the H-bridge, producing an output signal having a substantially constant propagation delay that is signal and load current independent. In other words, LLL circuit 200 may correct non-linear latency effects in the driver and improve the THD and SNR of the amplifier significantly.

During operation, an input signal (e.g. PWM B input or PWM D input) may propagate through the cascade of variable delay circuit 208 and H-bridge 210. As shown, an input PWM signal is received by variable delay circuit 208. Phase detector 204, which may be a phase/frequency detector or any other type of phase detector, may compare the edges of the signal from reference delay circuit 202 to the edges of the signal from slicer 212 and may provide a phase error signal to loop filter 206. Loop filter 206 may generate an adjustment signal to adjust variable delay circuit 208 to control the delay of the transitions within the input signal, which may be subsequently provided to H-bridge 210. The PWM output signal from H-bridge 210 may have substantially the same pulse widths as the PWM input signal into variable delay circuit 208 but with a propagation delay. The PWM input and output signals may have substantially the same frame rate, etc.

Slicer 212 may include a comparator and/or other circuitry—for example, a sampling circuit as described herein. Slicer 212 may be configured to receive the PWM output signal from H-bridge via polyresistor-based voltage divider 214 and provide, as output, edge transitions to phase detector 204 (note than certain configurations may include inverting the edge transitions before being received by phase detector 204). One slicer 212 is shown in the illustrated embodiment. Referencing FIG. 1, one slicer 212 and two LLL circuits 200 may be included for each of the PWM B and PWM D signals in circuit 100, for a total of two slicers 212 and four LLL circuits 200. Each slicer 212 may provide its output to two different LLL circuits 200 in certain embodiments. In one embodiment, the output from slicer 212 to one of LLL circuits 200 may be inverted. Thus, in one embodiment, there may be an LLL circuit 200 for each edge of each PWM signal (B and D) because different edges may have different delays, for a total of four LLL circuits 200. Likewise, there may be one slicer 212 for each PWM signal for a total of two slicers 212 with each slicer providing its output to two LLL circuits 200. Each slicer 212 may give two edges, one to one LLL circuit 200 and another to another LLL circuit 200.

Reference delay circuit 202 may be configured to receive the PWM input. Reference delay circuit 202 may further be configured to provide a delayed version of the PWM input signal to phase detector 204. In some embodiments, reference delay circuit 202 may apply fixed propagation delays to transition edges within the PWM input signal.

Phase detector 204 may compare the reference delay edge transitions with the compensated edge transitions from slicer 212 to determine a phase error for each of the transition edges. Phase detector 204 may generate phase error signals, which after filtering by loop filter 206, may be provided to variable delay circuit 208 to adjust the variable delay such that the overall delay from PWM input signal to PWM output signal is substantially equal to the reference delays provided by reference delay circuit 202. In one embodiment, the resulting overall delay through the circuit may be substantially constant for rising edges and falling edges independent of the load current of any load circuitry connected to H-bridge 210.

Loop filter 206 may be a first order filter, such as an integrator, for basic operation. The first order filter may be a lossy integrator or a lossless filter. In other embodiments, loop filter 206 can be a higher order filter (e.g., second order or higher order) for enhanced in-band attenuation, for instance, at low frequencies. Such a higher order filter may be any passive or active filter. Further, loop filter 206 may store a history of edge transitions. Loop filter 206 can be digital or analog. In one embodiment, loop filter 206 may be digital and may be adapted to provide an analog interpolation that is provided to variable delay circuit 208 to adjust the variable delay. Such analog interpolation may be used to apply particular variable delays in response to repeated patterns within the input signal, for example.

In one embodiment, one or more loop filters, such as loop filter 206, may be used to store a history of phase errors/edge placement errors for each type of edge. In such an instance, the edge placement errors may be averaged, combined, interpolated, or otherwise processed to produce a variable delay adjustment signal. In one instance, the phase errors of the individual edges may be linearly combined to produce a corrective adjustment for variable delay circuit 208. Depending on the implementation, the control signal provided by loop filter 206 to variable delay circuit 208 may be based on a weighted sum of the phase errors, an average, or other factors.

LLL circuit 200 may control pulse widths by controlling the edge transition position within a PWM frame at the output of the half H-bridge 210 by controlling the propagation delay of individual edges of the PWM input signal at the input of the half H-bridge 210. In some instances, the propagation delay of rising edges may be significantly different that than of falling edges. Further, propagation delay of negative pulses may be different from that of positive pulses. In such instances, it may be advantageous to independently control each of the transitions. LLL circuit 200 may track propagation delay variations and adjust the variable delay of variable delay circuit 208 to cancel out propagation delay variations. Because delay variations of H-bridge 210 may be signal dependent, the variable delay adjustment control signal from phase detector 204 may pre-distort and effectively cancel the distortion in the PWM output signals.

In one embodiment, LLL circuit 200 may be used to drive audio signals into a speaker. Depending on the frequency band of interest and depending on the filters used, LLL circuit 200 can be used to cancel load current dependent and signal content dependent propagation delays to produce a substantially constant propagation delay from input to output, linearizing the circuit. LLL circuit 200 may adjust timing of edge transitions at the input of the half H-bridges, based on delays measured in the PWM output signal so that the PWM output signal is substantially the same as the PWM input signal in terms of data rate, pulse widths, frequency, etc. Thus, the total propagation delay from PWM input signal to PWM output signal may remain substantially constant, independent of the content of the input signal and independent of load current.

FIG. 2 illustrates a single LLL circuit 200 of the two LLL circuits 200 of FIG. 1. In one embodiment, the illustrated LLL circuit 200 is configured to provide edge adjustments for rising edges of an input signal, such as a PWM B signal of a differential signal pair. Another LLL circuit may be duplicated (including loop filter, phase detector, etc.) that is configured to provide edge transition adjustments for falling edges of the input signal. The two LLL circuits may share a common slicer circuit. Further, the two LLL circuits may be duplicated to provide edge adjustments for rising and falling edges of a second input signal, such as a PWM D signal of the differential signal pair.

Turning now to FIG. 3, a block diagram of one embodiment of slicer circuit 300 is depicted. In the illustrated embodiment, slicer circuit 300 includes sampling circuit 302 and comparator 304. As shown, a PWM signal is coupled to one input of comparator 304 and to sampling circuit 302. Sampling circuit 302 is coupled to another input of comparator 304 and may be controlled by the illustrated sampling control signal.

Sampling circuit 302 may be configured to sample the PWM signal to generate a threshold voltage based on the average of the high and low voltage levels of the PWM signal. High and low voltage levels may be the output voltage levels when the input of the buffer circuit 104 is set to logic 1 or 0, respectively. Sampling circuit 302 may be further configured to provide the threshold voltage to comparator 304. In one embodiment, sampling circuit may be configured to alternately sample the high and low voltage levels of the PWM signal (this may also be described in terms of positive and negative phases of the PWM voltage). In some embodiments, a PWM signal look ahead is available and can be used as the sampling control signal. In other embodiments, the sampling control signal may be a delayed version of the PWM signal. As part of the sampling, sampling circuit 302 may store the sampled high and low voltage levels (positive or negative phase), respectively, in one or more capacitors of sampling circuit 302. The sampling/storing for each the high voltage level or low voltage level may occur at different points in time. For example, at a first time during operation of sampling circuit 302, the high voltage level may be sampled and stored into a capacitor. At a second time during operation of sampling circuit 302, the capacitor storing the sampled high voltage level may be discharged into a holding capacitor. In between the second and third times or at the same time depending on the embodiment, the low voltage level may be sampled into the same capacitor that stored the sampled high voltage level, or in some embodiments, into a different sampling/storing capacitor. As used herein, the phrase “at the same time” may include situations in which the sampled voltage is discharged and the other voltage is sampled according to the same clock edge. One of skill in the art would also recognize that the phrase “at the same time” encompasses situations in which there is some insubstantial difference in the relative switching, sampling, discharging, etc., times of two or more elements due to non-ideal conditions, even if the switching, sampling, and discharging events are triggered by the same clock edge. At a third time during operation, the capacitor storing the sampled low voltage level may be discharged into the same holding capacitor and the high voltage level may be sampled again. Thus, in various embodiments, while the high voltage level is sampled, the stored low voltage level may be discharged into a hold capacitor. Likewise, while the low voltage level is sampled, the stored high voltage level may be discharged into the same hold capacitor. Over time, the hold capacitor may be an approximate average or midlevel of the PWM signal (e.g., an average of the high and low voltage levels). The resulting average in the hold capacitor may be a more accurate and low-pass filtered version of the average of the positive and negative phase PWM output voltage when a PWM edge occurs.

In one embodiment, the sampling circuit performing sampling and dumping of the PWM low voltage level, and sampling and dumping of the PWM high voltage level may generate an average that contains built-in error (e.g., from load current dependent shift or undesired voltage differentials) introduced at the slicer circuit. Accordingly, the generated threshold may follow the actual midpoint of the edges and compensate for the built-in error so that the error introduced at the slicer circuit may not be passed on to the LLL circuit. Thus, the signal itself, rather than an idealization of the signal, may be used to generate the threshold.

A plurality of switches may control the sampling, storing, and redistribution of the sampled/stored voltages among the various capacitors. In one embodiment, a PWM generator that generates the PWM signal may control the switches. Because of the delay in the PWM buffer, the PWM generator may know in advance when the signal is going to change and therefore, also may know that the system should stop tracking, for example. Because the PWM generator knows when an edge will occur, sampling may occur just before the edge changes at the PWM buffer output because it may be highly likely that the signal has settled to the expected level (e.g., PWM low voltage level, PWM high voltage level) at that time. In other embodiments, sampling may occur at other points in time, such as approximately halfway between edge transitions, or sometime after an edge transition.

In some embodiments, sampling of the PWM voltage may occur just before an edge transition. For example, sampling of the positive PWM voltage (high voltage) may occur just before a falling edge of the PWM voltage. Similarly, the negative PWM voltage (ground) may be sampled just before a rising edge of the PWM voltage. In other embodiments, sampling may occur just after edge transitions, or approximately halfway between edge transitions.

In one embodiment, comparator 304 includes a pair of inputs. Comparator 304 is configured to receive a PWM voltage/signal at one of the inputs and the threshold voltage from sampling circuit 302 at the other input. Comparator 304 may be configured to perform edge detection on the received PWM voltage and the threshold voltage. The edge detection of comparator 304 may result in a digital edge timing waveform used for feedback in a compensation circuit (e.g., LLL circuit) of the class D amplifier.

Sampling the high and low voltage levels of the PWM signal to use in the threshold of the slicer circuit may offer many advantages. Using a fixed threshold may introduce distortion in the actual slicer circuit because it does not follow the supply rail voltage modulation caused by load current variation and because it may not account for output ground differentials. As a result, if a fixed threshold is used, the LLL circuit may not correct timing errors or non-linearity introduced by the slicer circuit itself. Continuous sampling and generating of the optimum slicing level may reduce the error introduced by the slicer circuit and result in significant performance improvements. Another advantage may be a significant reduction of rdson voltage drop effect, improving both SNR and THD. Because the driver has a non zero output resistance and the current that flows through it depends on the signal being amplified, the PWM is being offset up and down by the produced voltage drop that depends on the signal. If the threshold is determined simply on the supply voltages (before the voltage drop) and not by sampling, a timing error may be introduced in the slicer that will depend on the signal, hence creating undesired distortion. Because edges on the PWM exist that are not signal related, with spectral content outside the band of interest, the modulation caused by the signal-related timing errors will down mix that spectral content into the band of interest and therefore significantly reduce the SNR. By generating the threshold voltage as described herein, the error may be reduced by more than one order of magnitude and any degradation of THD and SNR may be greatly reduced.

Because the slicer circuit of FIG. 3 is insensitive to ground differentials, it may also avoid the need for extra bond-wires or package pins and the potential interference problems associated with them. The output driver is commonly located in an external chip or a high voltage technology based die on the same package. The slicer circuit may avoid the need to have bond-wires to carry either positive or negative supplies from the high voltage die or chip to the controller die or chip, which may save cost and potential technical problems associated with bond-wire interference.

The slicer circuit may further remove mismatch problems associated with having different resistance dividers for the supply and the PWM waveform. Because both the H-bridge driver PWM output and supply are high-voltage signals that may not be handled directly by the low voltage chip, they may have to be divided down by resistive dividers, which are physically different and a source of mismatch which ultimately may create SNR and THD degradation problems. The slicer circuit may avoid one of the resistance dividers and create the necessary signals from the same resistance divider thus avoiding the mismatch problems. Further, any mismatch between PWM B and PWM D resistance dividers may not cause degradation. For example, voltage thresholds used in each slicer may normalize to each slicer's respective resistance divider and therefore may not cause any timing errors. Further, the slicer circuit may include an inherent low-pass filtering function of out-of-band noise that may improve SNR. In addition, the slicer circuit may allow for overvoltage problems to be easily mitigated by utilizing a single resistor divider and hence not have to switch from one high voltage input to the other.

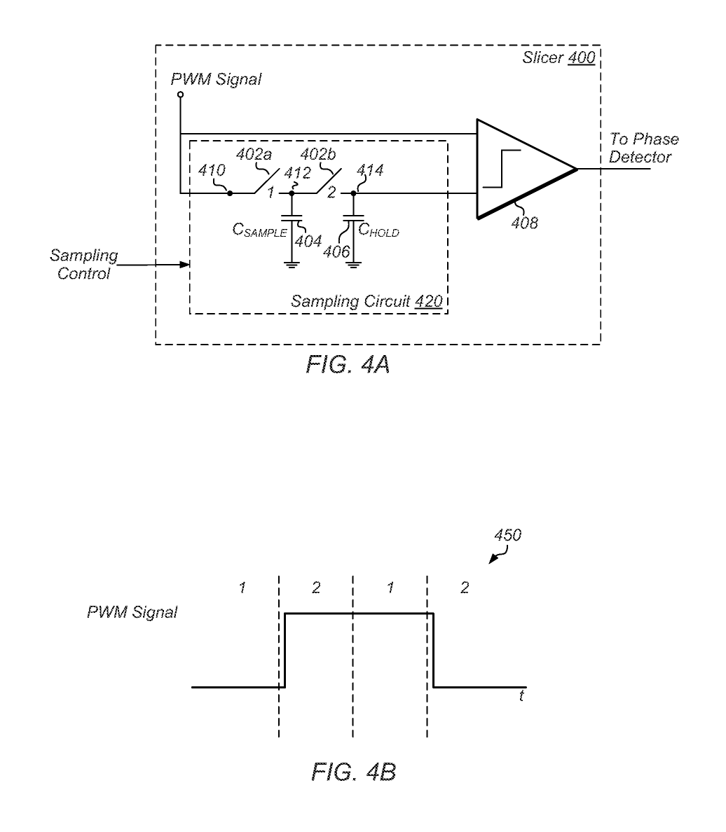

Turning now to FIG. 4A, a circuit diagram of one embodiment of sampling circuit 420 of slicer 400 is depicted. In the illustrated embodiment, sampling circuit 420 includes a plurality of switches and a plurality of capacitors. As shown, sampling circuit 420 includes two switches 402a and 402b and two capacitors, C_{SAMPLE} 404 and C_{HOLD} 406. In the illustrated embodiment, slicer 400 also includes comparator 408.

In the illustrated embodiment, sampling circuit 420 includes a first node 410 coupled to the PWM voltage and to a second node 412 via first switch 402a. The second node 412 may be coupled to a ground through a first capacitor, C_{SAMPLE} 404, and to a third node 414 via second switch 402b. The third node 414 may be coupled to the ground through a second capacitor, C_{HOLD} 406, and to an input of the comparator. C_{SAMPLE} 404 may be configured to alternately sample a positive phase and negative phase of the PWM voltage. C_{HOLD} 406 may be configured to hold the average of the sampled positive and negative voltage of the PWM signal. As a result, the hold capacitor may hold a threshold voltage of the PWM signal to provide to comparator 408.

Turning now to FIG. 4B, a timing diagram of a PWM voltage with switch designations is depicted. The numbers in the timing diagram correspond to which switch is closed at the corresponding time. Switch numbering is shown in FIG. 4A. At the first time period depicted, from a low-voltage PWM signal to just before the transition to high voltage, switch 1 is closed and switch 2 is open. Switch 1 corresponds to the leftmost switch, labeled “1” in FIG. 4A. At the second time period depicted, from just before the transition to high voltage to approximately halfway through the high voltage duration, switch “2” is closed and switch 1 is open. At the third time period depicted, from approximately halfway through the high voltage duration to just before the transition back to low voltage, switch 1 is closed and switch 2 is open. At the fourth and final time period depicted, from just before the transition back to low voltage, switch 2 is closed and switch 1 is open. Four time periods are shown in FIG. 4B but similar timing would continue during operation of the sampling circuit. In other embodiments, the time periods may be shifted such that instead of just prior to a voltage transition, time periods may begin or end a while after a voltage transition.

Referencing FIGS. 4A and 4B, one example operation sequence of sampling circuit 420 follows. At the first time period of FIG. 4B, switch 402a of FIG. 4A may close resulting in the positive phase of the PWM signal being sampled and stored in C_{SAMPLE} 404. Also during the first time period, switch 402b may be open such that C_{SAMPLE} 404 may not discharge while it is sampling the PWM signal. At the second time period of FIG. 4B, switch 402a may be open and switch 402b may be closed. As a result, the PWM signal may not be sampled and C_{SAMPLE} 404 may discharge into C_{HOLD} 406 which in turn may be connected to an input of comparator 408. At the third time period of FIG. 4B, switch 402a may close resulting in sampling the negative phase of the PWM signal and switch 402b may open such that C_{SAMPLE} 404 may not discharge while it is sampling the PWM signal. At the fourth and final time period of FIG. 4B, switch 402a may be open and switch 402b may be closed resulting in C_{SAMPLE} 404 discharging into C_{HOLD} 406 which in turn may be connected to an input of comparator 408. Because sampling circuit 420 alternates sampling the positive and negative phases of the PWM signal, the charge stored in C_{HOLD} 406 that is provided to an input of comparator 408 may be an average of the high and low voltage of the PWM signal. Accordingly, the generated threshold voltage that sampling circuit 420 provides to comparator 408 may be the average of the high and low voltage of the PWM signal

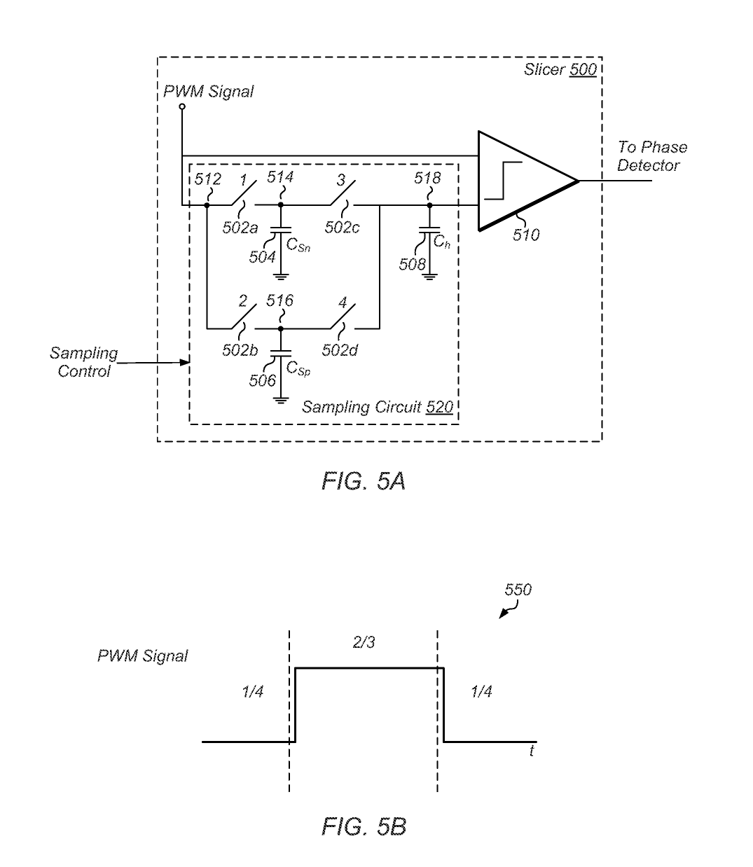

Turning now to FIG. 5A, a circuit diagram of one embodiment of sampling circuit 520 of slicer 500 is depicted. In the illustrated embodiment, sampling circuit 520 includes a plurality of switches and a plurality of capacitors. As shown, sampling circuit 520 includes four switches 502a-502d and three capacitors, C_{Sn} 504, C_{Sp} 506, and Cₕ 508. In the embodiment shown, slicer 500 also includes comparator 510.

In the illustrated embodiment, sampling circuit 520 includes a first node 512 coupled to the PWM voltage and to a second node 514 via first switch 502a and to a third node 516 via second switch 502b. The second node 514 is coupled to ground through a first capacitor, C_{Sn} 504, and to a fourth node 518 via third switch 502c. The third node 516 is coupled to ground through a second capacitor, C_{Sp} 506, and to the fourth node 518 via fourth switch 502d. The fourth node 518 is coupled to ground through a third capacitor, Cₕ 508, and to an input of comparator 510. C_{Sn} 504 may be configured to sample a negative phase of the PWM voltage, or the PWM low voltage level. Similarly, C_{Sp} 506 may be configured to sample a positive phase of the PWM voltage, or the PWM high voltage level. Cₕ 508 may be configured to hold an average of the sampled positive and negative voltages of the PWM signal. As a result, Cₕ 508 may hold an approximate average of the positive and negative voltage of the PWM signal. The components (e.g., switches, capacitors, etc.) of sampling circuits 420 and 520 of FIGS. 4A and 5A, respectively, and their corresponding structural equivalents may be referred to as a “means for sampling a PWM voltage to generate a threshold voltage based on an average of the positive and negative voltage of the PWM signal.”

Having two sets of capacitors may be beneficial in situations where the duty cycle of the PWM signal is not close to 50%. For instance, the PWM signal can have very long or very small pulses in which it may be beneficial to sample the high voltage and ground into separate capacitors instead of a shared capacitor.

Turning now to FIG. 5B, a timing diagram of a PWM voltage with switch designations is depicted. The numbers in the timing diagram correspond to which switch is closed at the corresponding time. Switch numbering is shown in FIG. 5A. At the first time period depicted, from a low voltage PWM signal to just before the transition to high voltage, switches “1” and “4” are closed and switches “2” and “3” are open. At the second time period depicted, from just before the transition to high voltage to just before the transition back to low voltage, switches 2 and 3 are closed and switches 1 and 4 are open. At the third and final time period depicted, from just before the transition back to low voltage to the end of the depicted timing diagram, switches 1 and 4 are closed and switches 2 and 3 are open. Three time periods are shown in FIG. 5B but similar timing would continue during operation of the sampling circuit. In other embodiments, the time periods may be shifted such that instead of just prior to a voltage transition, time periods may begin or end after a voltage transition or approximately at the voltage transition.

Referencing FIGS. 5A and 5B, one example operation sequence of sampling circuit 520 follows. At the first time period of FIG. 5B, switch 502a of FIG. 5A may be closed, resulting in the negative phase of the PWM signal being sampled and stored in C_{Sn} 504. Also during the first time period, switch 502d may likewise be closed such that any previously sampled positive phase of the PWM signal stored in C_{Sp} 506 may be discharged to Cₕ 508. Switches 502b and 502c may be open to prevent the negative phase from being stored in C_{Sp} 506 and to prevent C_{Sn} 504 from discharging while it is sampling the negative phase. At the second time period of FIG. 5B, switches 502b and 502c may be closed resulting in the positive phase of the PWM signal being sampled and stored in C_{Sp} 506 and the previously sampled and stored negative phase being discharged from C_{Sn} 504 to Cₕ 508. The third time period of FIG. 5B repeats the same sequence of switching, sampling, storing, and discharging of the first time period. As a result, the sampled and stored positive and negative phases of the PWM signal may be discharged into the same capacitor, Cₕ 508, which may be an approximate average of the PWM signal high and low voltage levels. The average of the PWM signal high and low voltage levels may be the generated threshold voltage that may be provided to comparator 510 so that comparator 510 may perform edge detection on the threshold voltage and the PWM signal.

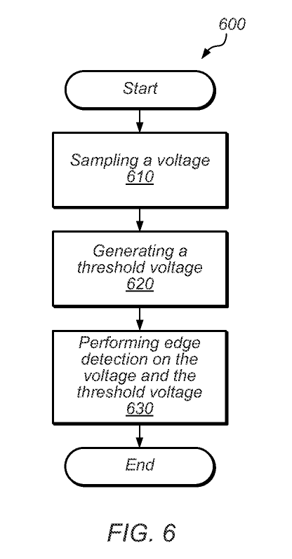

Turning now to FIG. 6, one embodiment of a method 600 for sampling a PWM voltage and generating a threshold voltage is shown. In one embodiment, slicer 300, including sampling circuit 302 and comparator 304, performs method 600. In some embodiments, method 600 may include additional (or fewer) steps than shown. The steps of method 600 may be initiated by a PWM generator or other circuitry.

In step 610, sampling circuit 302 may sample a voltage, such as from a PWM signal or other signal in which the duty cycle varies. In one embodiment, sampling circuit 302 may include multiple switches and capacitors to perform the sampling. For instance, one or more switches may be closed such that during a positive phase of the PWM signal, the PWM signal may be sampled and stored into a capacitor. During a negative phase of the PWM signal, one or more switches may be closed such that the PWM signal may be sampled and stored into a capacitor. Thus, the positive and negative phases of the PWM signal may be alternately sampled. The one or more switches that are closed during sampling and the capacitor into which the PWM signal is sampled may be the same switches and capacitor in some embodiments, or they may be different switches and capacitors in other embodiments.

In step 620, sampling circuit 302 may generate a threshold voltage. The threshold voltage may be based on an average of the sampled PWM voltages. In various embodiments, the stored average of the sampled positive and negative phases of the PWM voltage may be further stored in the same capacitor such that over time, the stored voltage in that same capacitor may approximate an average or midlevel of the PWM signal.

In step 630, comparator 304 may perform edge detection on the received PWM signal based on the received generated threshold voltage. Edge detection may result in a digital edge timing waveform used for feedback in a compensation circuit (e.g., LLL circuit) of a class D amplifier. The compensation circuit may provide a modified PWM input voltage to a buffer circuit (e.g., H-bridge) of the class D amplifier based on the digital edge timing waveform.

As noted above, performing edge detection on a threshold voltage based on samplings of the actual PWM signal may reduce distortion added by slicer 300 by correcting for timing errors and non-linearities introduced by the slicer. As a result, THD and SNR may be greatly improved.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. An apparatus, comprising:
a comparator having first and second inputs, wherein the comparator is configured to receive a pulse width modulation (PWM) signal at the first input;
a sampling circuit configured to sample the PWM signal to generate a threshold voltage based on an average of a high voltage level and a low voltage level of the PWM signal and to provide the threshold voltage to the second input of the comparator;
wherein the comparator is configured to perform edge detection on the first input with respect to the second input.

2. The apparatus of claim 1, wherein the sampling circuit comprises:
a first node coupled to the PWM signal and to a second node via a first switch;
the second node coupled to a ground through a first capacitor and to a third node via a second switch; and
the third node coupled to the ground through a second capacitor and to the second input of the comparator;
wherein the first capacitor is configured to alternately sample the high voltage level and the low voltage level of the PWM signal, and wherein the second capacitor is configured to hold the average of the sampled high and low voltage levels of the PWM signal.

3. The apparatus of claim 2, wherein to sample the PWM signal to generate a threshold voltage based on the average of the high and low voltage levels of the PWM signal, the sampling circuit is further configured to:
at a first time corresponding to the high voltage level of the PWM signal, close the first switch and open the second switch;
at a second time before a transition from the high voltage level to the low voltage level of the PWM signal, open the first switch and close the second switch;
at a third time corresponding to the low voltage level of the PWM signal, close the first switch and open the second switch; and
at a fourth time before a transition from the low voltage level to the high voltage level of the PWM signal, open the first switch and close the second switch.

4. The apparatus of claim 1, wherein the sampling circuit comprises:
a first node coupled to the PWM signal and to a second node via a first switch and to a third node via a second switch;
the second node coupled to a ground through a first capacitor and to a fourth node via a third switch;
the third node coupled to the ground through a second capacitor and to the fourth node via a fourth switch; and
the fourth node coupled to the ground through a third capacitor and to the second input of the comparator;
wherein the first capacitor is configured to sample the high voltage level of the PWM signal, wherein the second capacitor is configured to sample the low voltage level of the PWM signal, and wherein the third capacitor is configured to hold the sampled high and low voltage levels of the PWM voltage.

5. The apparatus of claim 4, wherein to sample the PWM signal to generate a threshold voltage based on the average of the high and low voltages of the PWM signal, the sampling circuit is further configured to:
at a first time corresponding to the high voltage level of the PWM signal, close the first switch and fourth switch, and open the second switch and third switch; and
at a second time before corresponding to the low voltage level of the PWM signal, open the first switch and fourth switch, and close the second switch and third switch.

6. The apparatus of claim 1, wherein to sample the PWM signal, the sampling circuit is configured to alternately sample the high voltage level and the low voltage level of the PWM signal, wherein to alternately sample the high and low voltage levels, the sampling circuit is configured to store the high and low voltage levels to one or more capacitors of the sampling circuit at different points in time.

7. The apparatus of claim 6, wherein to generate the threshold voltage, the sampling circuit is configured to:
store the sampled high voltage level to another one of the one or more capacitors of the sampling circuit when the sampling circuit samples the low voltage level; and
store the low voltage level to the another one of the capacitors of the sampling circuit when the sampling circuit samples the high voltage level.

8. The apparatus of claim 1, further comprising a buffer circuit configured to provide the PWM signal, wherein the apparatus is a class D amplifier.

9. The apparatus of claim 1, wherein the edge detection results in a digital edge timing waveform used for feedback in a compensation circuit of the apparatus.

10. The apparatus of claim 9, wherein the compensation circuit is configured to provide a modified PWM input signal to an input of a buffer circuit based on the digital edge timing waveform.

11. An apparatus, comprising:
an H-bridge circuit coupled to a sampling circuit, a comparator, and a latency locked loop (LLL) circuit, wherein the H-bridge circuit is configured to provide a buffered pulse width modulation (PWM) voltage to the sampling circuit and to a first input of the comparator;
wherein the sampling circuit is configured to generate a threshold voltage based on samples of the PWM voltage, and wherein the sampling circuit is further configured to provide the generated threshold voltage to a second input of the comparator;
wherein the comparator is configured to compare the generated threshold voltage with the provided PWM voltage, and wherein the comparator is further configured to provide a result of the comparison to the LLL circuit;
wherein the LLL circuit is configured to generate a compensated PWM voltage based on the result from the comparator, and wherein the LLL circuit is further configured to provide the compensated PWM voltage to the H-bridge circuit.

12. The apparatus of claim 11, wherein to generate the threshold voltage, the sampling circuit is further configured to:
sample a negative phase of the PWM voltage before a rising edge of the PWM voltage;
sample a positive phase of the PWM voltage before a falling edge of the PWM voltage; and
calculate a midlevel of the sampled positive and negative phase of the PWM voltage.

13. The apparatus of claim 12, wherein the sampling circuit includes a switch-capacitor circuit configured to perform the sampling of the negative and positive phases of the PWM voltage, and calculating the midlevel of the PWM signal.

14. The apparatus of claim 11, wherein a controller that includes the sampling circuit and comparator is configured to receive a PWM signal via a polyresistor, wherein the PWM signal used by the sampling circuit and comparator is based on a divided-down PWM signal received from the polyresistor.

15. A method, comprising:
a sampling circuit sampling a signal having a varying duty cycle;
the sampling circuit generating a threshold voltage based on an average of a high voltage level and a low voltage level of the sampled signal;
a comparator receiving the signal and the generated threshold voltage; and
the comparator performing edge detection on the received signal with respect to the generated threshold voltage.

16. The method of claim 15, wherein said sampling the signal comprises:
at a first time, sampling the high voltage of the signal; and
at a second time, sampling the low voltage of the signal.

17. The method of claim 16, wherein said sampling the high voltage level and said sampling the low voltage level includes storing a charge of the sampled high voltage level and a charge of the sampled low voltage level to first and second capacitors, respectively, of a plurality of capacitors in the sampling circuit.

18. The method of claim 17, wherein said generating the threshold voltage comprises:
at the second time, discharging the sampled high voltage level charge to a third capacitor of the plurality of capacitors; and
at a third time, sampling the high voltage level of the signal again; and
discharging the sampled low voltage level charge to the third capacitor;
wherein threshold voltage comprises an average of the sampled low and high voltage level charges in the third capacitor.

19. The method of claim 15, wherein the sampling and generating include:
a first switch closing and a second switch opening at a first time corresponding to the high voltage level of the signal allowing the high voltage level to be stored in a first capacitor;
the first switch opening and the second switch closing at a second time before a transition from the high voltage level to the low voltage level of the signal resulting in the stored high voltage level of the signal discharging into a second capacitor;
the first switch closing and the second switch opening at a third time corresponding to the low voltage level of the signal allowing the low voltage level to be stored in the first capacitor; and
the first switch opening and the second switch closing at a fourth time before a transition from the low voltage level to the high voltage level of the signal resulting in the stored low voltage level of the signal discharging into the second capacitor;
wherein a charge stored from the high and low voltage levels in the second capacitor approximates an average of the high and low voltage levels of the signal.

20. The method of claim 15, wherein the sampling and generating include:
a first switch and a fourth switch closing and a second switch and a third switch opening at a first time corresponding to high voltage level of the signal allowing the high voltage level to be stored in a first capacitor;
the second switch and the third switch closing and the first switch and the fourth switch opening at a second time corresponding to the low voltage level of the signal allowing the low voltage level to be stored in a second capacitor and allowing the stored high voltage level from the first capacitor to be discharged into a third capacitor; and
the first switch and the fourth switch closing and the second switch and the third switch opening at a third time corresponding to a next high voltage level of the signal allowing the next high voltage level to be stored in a first capacitor and allowing the stored low voltage level from the second capacitor to be discharged into the third capacitor;
wherein the third capacitor includes an average of the high and low voltage levels of the signal.
